(19) United States
(12) Patent Application Publication
(10) Pub. No.: US 2025/0118719 A1
(43) Pub. Date: Apr. 10, 2025

(54) CHIP PACKAGE WITH MULTIPLE HBM STACKS

(71) Applicant: Advanced Micro Devices, Inc., Santa Clara, CA (US)

(72) Inventors: Brett P. WILKERSON, Austin, TX (US); Alan D. SMITH, Austin, TX (US)

(21) Appl. No.: 18/752,735

(22) Filed: Jun. 24, 2024

Related U.S. Application Data
(60) Provisional application No. 63/543,236, filed on Oct. 9, 2023.

(51) Int. Cl. H01L 25/18; H01L 23/00; H01L 23/053; H01L 23/498; H01L 23/528; H01L 25/00; H10B 80/00

(52) U.S. Cl. CPC H01L 25/18; H01L 23/053; H01L 23/5283; H01L 24/08; H01L 24/80; H01L 25/50; H01L 23/49833; H01L 24/16; H01L 2224/08145; H01L 2224/16225; H01L 2224/80895; H01L 2224/80896; H01L 2924/1431; H01L 2924/1436; H10B 80/00

(57) ABSTRACT

Disclosed herein are chip packages that integrate multiple compute dies through a single interposer die to a memory stack. The interposer die includes memory controller circuitry that allowing multiple compute dies to access the memory stack in an efficient manner.

### CROSS-REFERENCE TO RELATED APPLICATIONS

This application claims priority to the U.S. Provisional Patent Application Ser. No. 63/543,236 filed Oct. 9, 2023 of which is incorporated herein by reference in its entirety.

### TECHNICAL FIELD

Embodiments of the present invention generally relate to chip packages having memory stacks, and in particular, chip packages that interface one or more compute die stacks with multiple memory stacks within a singular chip package.

### BACKGROUND

Electronic devices, such as tablets, computers, copiers, digital cameras, smart phones, control systems, automated teller machines, data centers, artificial intelligence system, and machine learning systems among others, often employ electronic and/or photonics components which leverage chip packages for increased functionality and higher component density. Conventional chip packaging schemes often utilize a package substrate, often in conjunction with a through-silicon-via (TSV) interposer substrate and/or other such as FanOut and/or silicon bridging and/or substrate with glass and/or Si and/or organic core, to enable a plurality of integrated circuit (IC) dies to be mounted to a single package substrate. The IC dies are mounted to a top surface of the package substrate while a bottom surface of the package substrate is mounted to a printed circuit board (PCB).

In many applications, memory dies are integrated into the chip package to reduce the distance between the memory dies and compute dies of the chip package. The shortened distance reduces power consumption and increases device performance. One type of chip package having both a stack of memory dies and at least one connected compute die is known as a high bandwidth memory (HBM). The HBM stack conventionally includes an I/O buffer die upon which the memory dies are stacked. The I/O buffer die also includes the memory controller. However, in most conventional chip packages having a HBM die stack generally have compute dies that have complex route between each compute die and the I/O buffer and memory dies of with a particular HBM die stack, often requiring routing through the package substrate. The complex routing creates scheduling complexity that slows device performance. Additionally, the complex routing often requires a larger, more expensive interposer and package substrate to accommodate the increased number of routing traces without generating excessive unwanted noise. The larger interposers and package substrates increase the manufacturing complexity and cost, and contribute to slower performance, which are all undesirable.

Therefore, a need exists for improved chip packages that interface multiple compute dies with memory stacks within a singular chip package.

### SUMMARY

Disclosed herein are chip packages that integrate multiple compute dies through a single interposer die to a memory stack. The interposer die includes memory controller circuitry that allow multiple compute dies to access the memory stack in an efficient, scalable, robust, and cost efficient manner.

In one example, a chip package is provided that includes a substrate, an integrated circuit (IC) interposer die, a compute die stack, and a memory stack. The IC interposer die and the memory stack are mounted on the substrate. The compute die stack is mounted on the IC interposer die. The memory stack mounted is electrically coupled to the compute die stack through the IC interposer die.

In another example, the compute die stack further includes at least a first compute die and a second compute die. The first compute die and the second compute die may both include central processing unit (CPU) cores. Alternatively, the first compute die and the second compute die may both include accelerated compute cores. In other examples, one of the first and second compute dies may include central processing unit (CPU) cores while the other of the first and second compute dies may include accelerated compute cores.

In some examples, the compute die stack may include a carrier die disposed over one or more compute dies. The carrier die may be circuit free, such as not having any functional integrated circuitry. The carrier die may be fusion bonded to one or more of the compute dies. The fusion bond may utilize an oxide layer. In some examples, the chip package may include mold compound disposed between the memory stack and the carrier die of the compute die stack. In some examples, a metal layer may be formed in contact with a top surface of the mold compound disposed between the memory stack and the carrier die of the compute die stack, a top surface of the memory stack, and a top surface of the carrier die. In some examples, the chip package may include a lid disposed over the memory stack and the carrier die. Thermal interface material may be disposed in contact with both the metal layer and the lid. The thermal interface material may be a liquid metal or phase change material. One example of a suitable liquid metal is indium.

In some examples, the substrate upon which the IC interposer die is mounted is an interposer, and the interposer is mounted on a package substrate.

Surface mounted components may be disposed on the package substrate and electrically connected to the IC interposer die through the package substrate and interposer.

In some examples, the chip package includes at least one integrated passive device (IPD) mounted to the substrate and electrically connected to the IC interposer die through the substrate. The IPD may be a deep trench capacitor, an inductor, a resistor or other passive circuit element.

Mold compound may be disposed between the memory stack, the IPD and the carrier die. A metal layer may be formed in contact with a top surface of the mold compound, a top surface of the memory stack, a top surface of the IPD, and a top surface of the carrier die. A lid may be disposed over the memory stack, the IPD, and the carrier die, and thermal interface material may be disposed in contact with both the metal layer and the lid.

In some examples, the compute die stack includes a first compute die, a second compute die, a carrier die disposed over first and second compute dies, and a dummy die disposed between the IC interposer die and the carrier die. The dummy die may be circuit free. The dummy die may be a block of silicon. The dummy die may be fusion bonded to at least two of the first compute die, the second compute die, the IC interposer die, and the carrier die. The dummy die may be fusion bonded to the IC interposer die between the second compute die and a first edge of the IC interposer die, the first compute die disposed between the second compute die and a second edge of the IC interposer die, the first and second compute dies and the dummy die disposed between the first and second edges of the IC interposer die.

Compute dies of the compute die stack may be hybrid bonded to one or both of the IC interposer die and another compute die of the compute die stack.

The IC interposer die may include memory controller circuity and cache memory circuity. The memory controller circuity is coupled to compute dies of the compute die stack and the IC interposer die without routing signals through the substrate. The cache memory circuity is also coupled to both the first and second compute dies without routing signals through the substrate. The interposer die may further include network on a chip (NOC) circuitry; peripheral component interconnect express (PCIe) circuity; memory physical layer (PHY) circuitry configured to communicate with the memory stack; die to die PHY configured to communicate with at least one of the first and second compute dies; and I/O PHY configured to communicate with a device remote from the chip package.

The chip package may be configured to include solder balls for connecting to a printed circuit board, or exposed contact pads for interfacing with a socket (the socket typically mounted to a printed circuit board).

In still another example, a chip package includes a substrate, a first integrated circuit (IC) interposer die, a first compute die stack, a first memory stack, and a lid. The first IC interposer die and the first memory stack are mounted on the substrate. The first IC interposer die includes memory controller circuity. The first compute die stack is mounted on the first IC interposer die. The first compute die stack includes at least a first compute die and a second compute die that are both communicatively coupled with the memory controller circuity. The first memory stack is mounted on the substrate and is electrically coupled to the memory controller circuity through the substrate. The lid is disposed over the first memory stack and the first compute die stack. A thermal interface material is disposed in contact with both the first compute die stack and the lid.

In one example, the chip package includes a second compute die stack mounted on the first IC interposer die. The second compute die stack includes a plurality of compute dies communicatively coupled with the memory controller circuity.

In one example, the chip package includes a second memory stack mounted on the substrate and electrically coupled to the memory controller circuity through the substrate.

In one example, the chip package includes a second IC interposer die and a second memory stack both mounted on the substrate. The chip package also a second memory stack. The second IC interposer die includes memory controller circuity. The second compute die stack includes a plurality of compute dies communicatively coupled with the memory controller circuity of the second IC interposer die. The second memory stack is electrically coupled to the memory controller circuity of the second IC interposer die through the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one example of a chip package having a memory stack, a compute die stack and an integrated circuit (IC) interposer die. The memory stack and the IC interposer die are mounted on a common substrate, while the compute die stack is mounted on the IC interposer die. In the example of FIG. 1, the compute die stack includes first compute die stacked on the IC interposer die, and a second compute die stacked on the first compute die in a vertical orientation.

FIG. 2 is a schematic sectional view of another example of a chip package having a memory stack, a compute die stack and an integrated circuit (IC) interposer die. The memory stack and the IC interposer die are mounted on a common substrate, while the compute die stack is mounted on the IC interposer die. In the example of FIG. 1, the compute die stack includes at least two first compute dies stacked on the IC interposer die in a horizontal orientation.

FIG. 3 is a schematic block diagram of an IC interposer die interfaced with one or more memory stacks and one or more compute die stacks that may be utilized in any of the chip packages contemplated herein.

FIG. 4 is a schematic sectional view of one example of a compute die stack mounted to an IC interposer die that may be utilized in any of the chip packages contemplated herein.

FIG. 5 is a schematic sectional view of another example of a compute die stack mounted to an IC interposer die that may be utilized in any of the chip packages contemplated herein.

FIG. 6 is a schematic sectional view of yet another example of a compute die stack mounted to an IC interposer die that may be utilized in any of the chip packages contemplated herein.

FIG. 7 is a schematic plan view of a portion of a chip package illustrating relative exemplary positions of memory stacks, compute die stacks and integrated circuit (IC) interposer dies.

FIG. 8 is a schematic plan view of a portion of another chip package illustrating relative exemplary positions of memory stacks, compute die stacks and integrated circuit (IC) interposer dies. The exemplary chip package of FIG. 8 including at least one integrated passive device (IPD) coupled adjacent the memory stacks to a common substrate.

FIGS. 9 and 10 are partial sectional views of exemplary hybrid bonding interface between a compute die of a compute die stack and an integrated circuit (IC) interposer die.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are chip packages that integrate multiple compute dies through a single integrated circuity (IC) interposer die to a memory stack. The IC interposer die includes memory controller circuitry that allow multiple compute dies to access the memory stack more efficiently as compared to conventional chip packages, resulting in a scalable, robust, and cost efficient design. In some examples, the compute dies within the chip stack leverage hybrid bonding, thus increasing the communication bandwidth between the compute dies. The compute die stack may also be hybrid bonded to the IC interposer die, thus increasing the communication bandwidth between the compute dies and the IC interposer die. Having the compute die stack hybrid bonded to the IC interposer die also avoids having to route communication between the compute die stack and the memory controller and cache of IC interposer die pass through the substrate, which also increases performance and reliability. The use of hybrid bonding allows the interconnect configuration (i.e., bond pad location) on the IC interposer die to be fabricated differently without altering the IC interposer die itself. Thus, different compute dies may be connected in the same location of a single IC interposer die design, thus providing increased manufacturing flexibility at reduced costs. For example, both a compute die configured as a central processing unit (CPU) and a compute die configured as a graphics processing unit (GPU) can be mounted to the same IC interposer die simply by changing the configuration of the hybrid bonding layers. Moreover, the modular arrangement of the IC interposer die, memory stacks and compute dies makes the chip package readily scalable. The number and position of the modular arrangement components of the chip package may be selected and arranged for various compute applications without the need for new die or interposer designs. As a result, the chip package provides increased application flexibility at reduced manufacturing costs.

In one example, a chip package is provided that includes a substrate, an integrated circuit (IC) interposer die, a compute die stack, and a memory stack. The IC interposer die and the memory stack are mounted on the substrate. The compute die stack is mounted on the IC interposer die. The memory stack mounted is electrically coupled to the compute die stack through the IC interposer die.

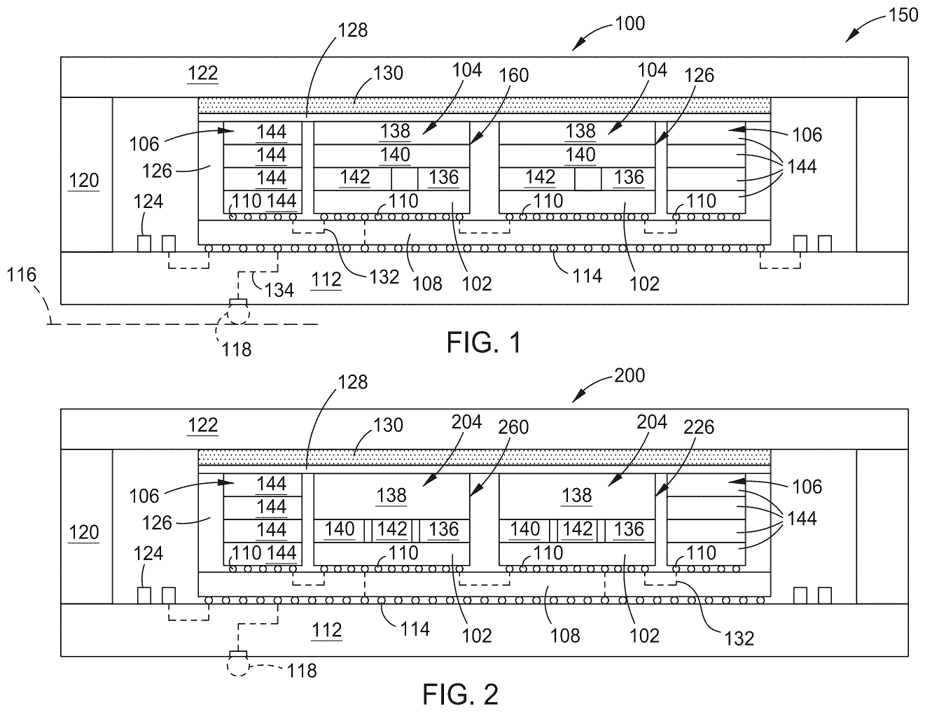

Turning now to FIG. 1, a schematic sectional view of one example of a chip package 100 is provided. The chip package 100 includes at least one integrated circuit (IC) interposer die 102, at least one compute die stack 104, and at least one memory stack 106. Although in the exemplary the chip package 100 includes two IC interposer dies 102 shown in FIG. 1, the chip package 100 may include one to as many IC interposer dies 102 as space permits to achieve desired functionality. Similarly, the chip package 100 illustrated in FIG. 1 may include one to as many memory stacks 106 as space permits to achieve desired functionality. Also, each IC interposer die 102 may include one to as many compute die stacks 104 IC as space permits to achieve desired functionality.

The memory stack 106 and the IC interposer die 102 are mounted on a common substrate. The substrate may be a package substrate. Alternatively as shown in FIG. 1, the substrate may be an interposer 108 that is mounted to a package substrate 112. The memory stack 106 and the IC interposer die 102 are electrically and mechanically coupled to the interposer 108 by interconnects 114. The interconnects 114 may be solder bumps, hybrid bonding, and may optionally or alternatively include a redistribution layer or other type of routing fanout. The interposer 108 includes interposer routing 132 that connects the functional circuitry of the memory stack 106 and the IC interposer die 102. The interposer routing 132 is also connected to package routing 134 formed in the package substrate 112. Thus, the package routing 134 of the package substrate 112 is coupled to the functional circuitries of the memory stack 106 and the IC interposer die 102 through the interposer routing 132.

The side of the package substrate 112 facing away from the IC interposer die 102 includes a plurality of exposed bond pads. The exposed bond pads may be configured to mate with corresponding pins of a socket mounted on a printed circuit board 116 to form an electronic device 150. Alternatively as illustrated in FIG. 1, solder balls 118 may be formed on the exposed bond pads of the package substrate 112 and utilized to mount the chip package 100 to a printed circuit board 116 to form the electronic device 150.

The package substrate 112 may include an optional stiffener 120. The stiffener 120 has a ring shape surrounds the memory stack 106 and the IC interposer die 102. The stiffener 120 is affixed to the top surface of the package substrate 112, thus making the package substrate 112 and ultimately the chip package 100 less prone to warpage, improving the reliability and performance of the chip package 100.

The memory stacks 106 are generally mounted adjacent the IC interposer dies 102. In the exampled depicted in FIG. 1, one or more memory stacks 106 are directly connected to the adjacent IC interposer die 102 via a high bandwidth routing formed in the interposer routing 132 of the interposer 108. Each of the memory stacks 106 includes a plurality of stacked memory dies 144. Using the plane of the interposer 108 as a horizontal reference, the memory dies 144 are vertically stacked. The memory dies 144 within each memory stack 106 can be interconnect via solder interconnect, via hybrid bonding, or other suitable technique. The memory dies 144 within a common memory stack 106 may be volatile memory, such as static random-access memory (SRAM), dynamic random-access memory (DRAM) or other suitable volatile memory type. Optionally, one or more of the memory dies 144 within a common memory stack 106 may be non-volatile memory, such as ferroelectric random-access memory (FeRAM) and magnetoresistive random-access memory (MRAM) or other suitable non-volatile memory type. The memory types of the memory dies 144 of one memory stack 106 may be the same or different than the memory types of the memory dies 144 of another memory stack 106 adjacent a common IC interposer die 102, or another memory stack 106 disposed in another region of the chip package 100 and adjacent a different IC interposer die 102 of the chip package 100.

In one example, the bottom memory die 144 of the memory die stack 106 is configured as a buffer die, having I/O circuitry. In another example, the bottom memory die 144 of the memory die stack 106 is configured as a volatile or non-volatile memory die 144. The number of memory dies 144 within common memory stack 106 may range from 2 to as many as desired. In one example, the number of memory dies 144 within common memory stack 106 is 4 to about 16. The number of memory dies 144 within different memory stacks 106 of the chip package 100 typically are the same. However, memory stacks 106 having different numbers of memory dies 144 may be utilized. When memory stacks 106 having different numbers of memory dies 144 are utilized, the memory stacks 106 may be configured to have the same height. For example, the height difference between stacks 106 may be compensated for by using memory dies 144 having different thicknesses and/or the use of one or more dummy dies on top of the memory stack 106.

The compute stack 104 is mounted to the IC interposer die 102 on a side of the IC interposer die 102 opposite the interposer 108. The interposer die 102 and compute die stack 104 form an interposer die/compute die stack assembly 160. There may be one or more compute stacks 104 coupled to each IC interposer die 102. For example, there may be two or more compute stacks 104 coupled to a single IC interposer die 102. Each compute stack 104 is electrically and mechanically coupled to the IC interposer die 102 by interconnects, such as solder bumps, hybrid bonding, or other suitable technique. In the example depicted in FIG. 1, the compute stack 104 is hybrid bonded to the IC interposer die 102.

The compute stack 104 includes a plurality of compute dies. In the example depicted in FIG. 1, the compute stack 104 includes a first compute die 140 and a second compute die 142. The compute stack 104 may include additional compute dies not shown. Although the first compute die 140 is shown vertically stacked on the second compute die 142, with second compute die 142 shown vertically stacked on the IC interposer die 102 in FIG. 1, the first and second compute dies 140, 142 may be horizontally stacked side by side the IC interposer die 102 as shown in FIG. 2.

Continuing to refer to FIG. 1, the first compute die 140 and the second compute die 142 may be the same type of die or a different type of processor die. The first compute die 140 and/or the second compute die 142 may be the same type of processor die or a different type of processor die than another compute die included in the same compute stack. The second compute die 142 is electrically and mechanically coupled to the IC interposer die 102 by interconnects, such as solder bumps, hybrid bonding, or other suitable technique. In the example depicted in FIG. 1, the second compute die 142 is hybrid bonded to the IC interposer die 102. Similarly, the first compute die 140 is electrically and mechanically coupled to the second compute die 142 by interconnects, such as solder bumps, hybrid bonding, or other suitable technique. In the example depicted in FIG. 1, the second compute die 142 is hybrid bonded to the second compute die 142. As discussed above, hybrid bonded desirably improves communication speeds and allows for increased bandwidth. Moreover, hybrid bonding allows for compute dies having different configurations of bond pad locations to be mounted on the same IC interposer die design since the bond pad in the hybrid bonding layer may be easily relocated without need for a different IC interposer die.

In one example, the functional circuitry of both the first compute die 140 and the second compute die 142 include central processing unit (CPU) cores. As such, each of the first and second compute dies 140, 142 may be referred to as a CPU die or CPU chiplet. The functional circuitry of the first and second compute dies 140, 142 may also include System Management Unit (SMU). The SMU is circuitry configured to monitor thermal and power conditions and adjust power and cooling to keep the dies 140, 142 functioning as within specifications. The functional circuitry of the first and second compute dies 140, 142 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of both the first compute die 140 and the second compute die 142 include accelerated compute cores. As such, each of the first and second compute dies 140, 142 may be referred to as an accelerator die or accelerator chiplet. The first and second compute dies 140, 142 may also be referred to as a graphic processing unit (GPU) die or GPU chiplet. The accelerated compute cores contained in the functional circuitry of the first and second compute dies 140, 142 generally includes math engine circuitry. The math engine circuitry is generally designed for task specific computing, such as used data center computing, high performance computing and Al/ML computing. Along with the accelerated compute cores, functional circuitry of the first compute die 140 and the second compute die 142 may also include SMU circuitry and DFX circuitry.

In other examples, the functional circuitry the first compute die 140 and the second compute die 142 are different. For example, the first compute die 140 may include accelerated compute cores, while the second compute die 142 includes CPU cores. One or more compute dies, when present in the compute stack 104, may include CPU cores and/or an accelerated compute cores.

The compute die stack 104 may additionally include a carrier die 138 disposed over the compute dies 140, 142. The carrier die 138 generally is the top die in the compute die stack 104, located farthest from the IC interposer die 102. The carrier die 138 is generally a block of silicon material that provides good heat transfer out of the compute die stack 104. The carrier die 138 may be thicker than one or both of the compute dies 140, 142, thus providing increased structural rigidity and increase resistance to warpage within the compute die stack 104, which makes connections between compute dies 140, 142 more reliable and robust. The carrier die 138 may be circuit free, i.e., free from routing, passive and active circuit devices. The carrier die 138 is adhered to one or both of the compute dies 140, 142. For example, the carrier die 138 is adhered to the first compute die 140 in the chip package 100 of FIG. 1, while the carrier die 138 is adhered to both of the compute dies 140, 142 in the chip package 200 of FIG. 2. The carrier die 138 may be adhered to the compute die(s) using any suitable adhesive or technique. In one example, the carrier die 138 is fusion bonded to the compute die(s). In such an example, an oxide layer is disposed between the carrier die 138 and the compute die(s) to enhance the fusion bonding process. Fusion bonding increases the structural rigidity of the compute die stack 104, and makes connections between compute dies 140, 142 more reliable and robust. Optionally, a single carrier die 138 may span more than one compute die stack 104.

The compute die stack 104 may additionally include a dummy die 136 disposed over or next to one or more of the compute dies 140, 142. The dummy die 136 generally is between the carrier die 138 and the IC interposer die 102. The dummy die 136 may alternatively contact one of the carrier die 138 and the IC interposer die 102, and also contact one or both of the compute dies 140, 142. The dummy die 136 is generally a block of silicon material that provides good heat transfer through the compute die stack 104. The dummy die 136 also provide mechanical stability across the width of the compute die stack 104. The dummy die 136 may be circuit free, i.e., free from routing, passive and active circuit devices. The dummy die 136 is adhered to the overlying and underlying dies (i.e., two of the compute dies 140, 142, IC interposer die 102, and carrier die 138. For example, the dummy die 136 is adhered to the first compute die 140 and the IC interposer die 102 in the chip package 100 of FIG. 1, while the dummy die 136 is adhered to both of the IC interposer die 102 and the carrier die 138 in the chip package 200 of FIG. 2. The dummy die 136 may be adhered to the neighboring overlying and underlying dies using any suitable adhesive or technique. In one example, the dummy die 136 is fusion bonded to the neighboring overlying and underlying dies. In such an example, an oxide layer is disposed between the dummy die 136 and each of the neighboring overlying and underlying dies to enhance the fusion bonding process. As with the carrier die 138, fusion bonding of the dummy die 136 increases the structural rigidity of the compute die stack 104, and makes connections between compute dies 140, 142 more reliable and robust. Optionally, more than one dummy die 136 may be used in a single compute die stack 104.

The chip package 100 further includes a mold compound 126 disposed between the memory stack 106 and the compute stack 104. The mold compound 126 provides structural rigidity to the chip package 100, improving warpage resistance while also protecting the electrical components.

In one example, a top surface of the mold compound 126, a top surface of the memory stack 106, and a top surface of the compute stack 104 are exposed on coplanar. The exposed top surfaces can be interfaced with a thermal management device (such as a heat sink, not shown) of the electronic device 150, or allowed to radiate heat into the environment. In the example depicted in FIG. 1, the top surfaces of the mold compound 126, the memory stack 106, and the compute stack 104 are covered by a lid 122. The lid 122 is generally comprised of a material having good thermal conductivity, such as a metal. In one example, the lid 122 is a metal, such as copper, aluminum or stainless steel. The lid 122 may optionally be plated with another metal, such as nickel. The lid 122 may optionally couple to the package substrate 112, for example by fasteners or the stiffener 120 (via adhesives).

The top surfaces of the mold compound 126, the memory stack 106, and the compute stack 104 may be covered by a metal layer 128 to enhance heat transfer to the lid 122. The metal layer 128 may be copper, aluminum, nickel, other suitable material. A thermal interface material (TIM) 130 may be disposed between and in contact with the metal layer 128 and underside of the lid 122. The TIM 130 may be a liquid metal, phase change material, thermal grease, thermal pad, or other suitable heat transfer material. In one example, the TIM 130 is indium.

Continuing to refer to FIG. 1, the package substrate 112 may also include surface mounted components 124 that are coupled to the IC interposer die 102 via the interposer routing 132. The surface mounted components 124 may be integrated passive devices (IPDs), such as capacitors, inductors, and resistors, among others. In one example, the surface mounted components 124 are capacitors. In addition or alternatively, some or all of the surface mounted components 124 may be located as IPDs in other locations of the chip package 100. For example, IPDs may be located within or attached to the interposer 108, within the package substrate 112, in a redistribution layer, or other suitable location within the chip package 100.

As briefly described above, FIG. 2 is a schematic sectional view of another example of a chip package 200 at least one integrated circuit (IC) interposer die 102, at least one compute die stack 204, and at least one memory stack 106. The interposer die 102 and compute die stack 204 form an interposer die/compute die stack assembly 260. The chip package 200 is configured essentially the same as the chip package 100 illustrated in FIG. 1, except that the interposer die/compute die stack assembly 260 replaces the interposer die/compute die stack assembly 160. The compute die stack 204 of the interposer die/compute die stack assembly 260 has the compute dies 140, 142 arranged in a horizontally stacked orientation. Additionally, the compute die stack 204 may optionally include at least one dummy die 136 fusion bonded to the IC interposer die 102. In the example depicted in FIG. 2, the dummy die 136 is disposed between the second compute die 142 and a first edge of the IC interposer die 102. The first compute die 140 is disposed between the second compute die 142 and a second edge of the IC interposer die 102. The first and second compute dies 140, 142 and the dummy die 136 are disposed between the first and second edges of the IC interposer die 102.

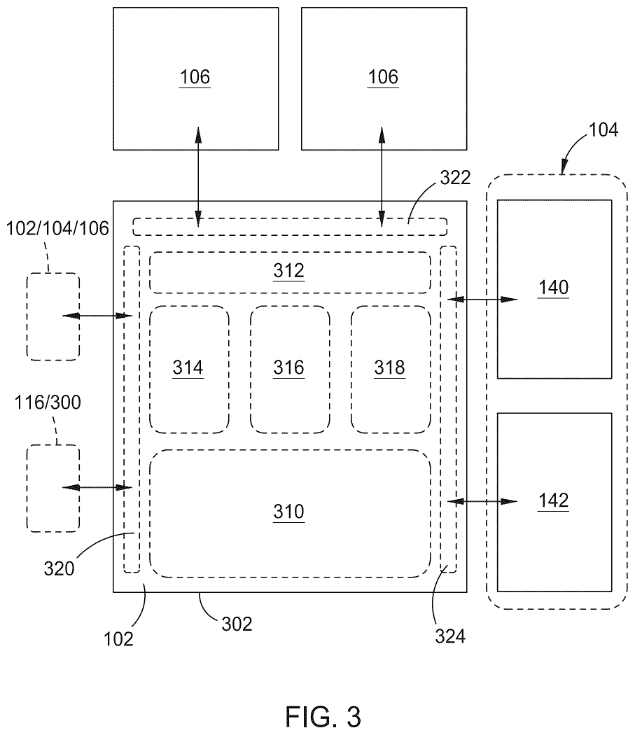

FIG. 3 is a schematic block diagram of one example of the IC interposer die 102 interfaced with one or more memory stacks 106 and one or more compute die stacks 104 that may be utilized in any of the chip packages contemplated herein, such as but not limited to chip packages 100, 200, 800, among others. The IC interposer die 102 may alternatively have other configurations. The functional circuitry of the IC interposer die 102 illustrated in FIG. 3 includes memory controller circuity 312 coupled to both the first and second compute dies 140, 142 without routing signals through the package substrate 112 or the interposer 108. The functional circuitry of the IC interposer die 102 also includes cache memory circuity 310. The cache memory circuity 310 is coupled to both the first and second compute dies 140, 142 without routing signals through the package substrate 112 or the interposer 108. The cache memory circuity 310 provides a large common cache for the compute dies of the compute stack 104 mounted to the IC interposer die 102.

The functional circuitry of the IC interposer die 102 may also includes peripheral component interconnect express (PCIe) circuity 314, memory physical layer (PHY) circuitry 322 configured to communicate with the memory stack 106, die to die PHY 324 configured to communicate with at least one or more compute stacks 106, and I/O PHY 320 configured to communicate with an integrated circuit device 300 remote from the chip package 100, or a printed circuit board 116 via the package substrate 112. The I/O PHY 320 may also be configured to communicate with other IC interposer dies 102 and/or compute stacks 104 that are remove from the interposer die 102 in which the I/O PHY 320 resides. The I/O PHY 320 may also be configured to communicate with other memory stacks 106 residing in the chip package 100.

The functional circuitry of the IC interposer die 102 may also include functional block 316 that serializes and deserializes digital data used in high-speed chip-to-chip communication (e.g., serdes circuitry). The functional circuitry of the IC interposer die 102 may also include one or more other functional blocks 318 for performing other functions of a network on a chip (NOC).

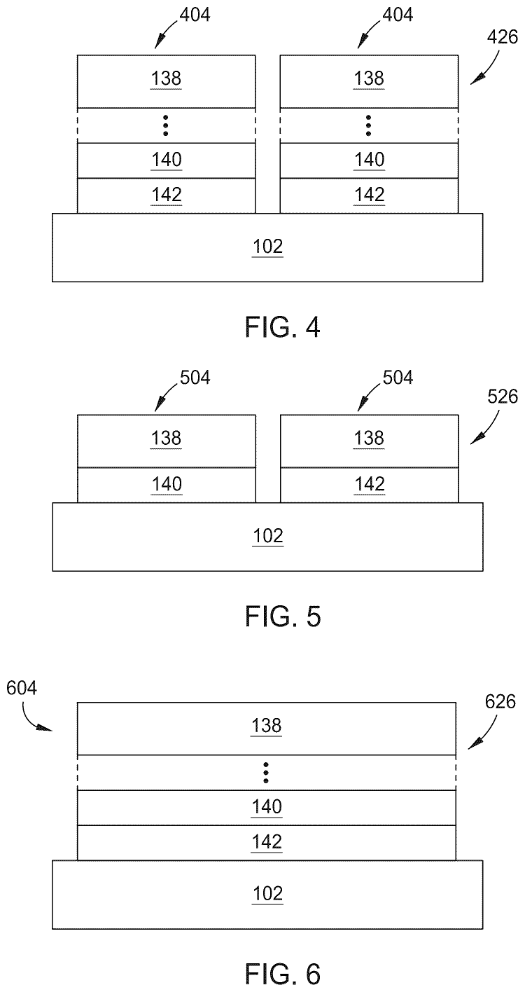

FIG. 4 is a schematic sectional view of one example of an interposer die/compute die stack assembly 426. The interposer die/compute die stack assembly 426 includes one or more compute die stacks 404. Two compute die stacks 404 are shown in FIG. 4, but the compute die stacks 404 may number from 1 to as many as can be reasonably accommodated on the IC interposer die 102. The compute die stacks 404 may include optional dummy dies 136 as described above with reference to FIGS. 1 and 2. The interposer die/compute die stack assembly 426 may be utilized in any of the chip packages contemplated herein, such as but not limited to chip packages 100, 200, 800, among others.

In the example depicted in FIG. 4, two compute dies 140, 142 are shown in each compute die stack 404. However, there may be none, one or more additional compute dies disposed between the first compute die 140 and the carrier die 138.

FIG. 5 is a schematic sectional view of one example of an interposer die/compute die stack assembly 526. The interposer die/compute die stack assembly 526 includes one or more compute die stacks 504. Two compute die stacks 504 are shown in FIG. 5, but the compute die stacks 504 may number from 1 to as many as can be reasonably accommodated on the IC interposer die 102. The compute die stacks 504 may include optional dummy dies 136 as described above with reference to FIGS. 1 and 2. The interposer die/compute die stack assembly 526 may be utilized in any of the chip packages contemplated herein, such as but not limited to chip packages 100, 200, 800, among others.

In the example depicted in FIG. 5, each compute die stack 504 includes a single compute die 140, 142. Each compute die 140, 142 is covered by a separate carrier die 138. Optionally, a single carrier die 138 may span to or more of the die stack 504.

FIG. 6 is a schematic sectional view of one example of an interposer die/compute die stack assembly 626. The interposer die/compute die stack assembly 526 includes one or more compute die stacks 604. A single compute die stack 604 is shown in FIG. 6, but the compute die stacks 604 may number from 1 to as many as can be reasonably accommodated on the IC interposer die 102. The compute die stack 604 may include optional dummy dies 136 as described above with reference to FIGS. 1 and 2. The interposer die/compute die stack assembly 626 may be utilized in any of the chip packages contemplated herein, such as but not limited to chip packages 100, 200, 800, among others.

In the example depicted in FIG. 6, two compute dies 140, 142 are shown in the compute die stack 604. However, there may be none, one or more additional compute dies disposed between the first compute die 140 and the carrier die 138.

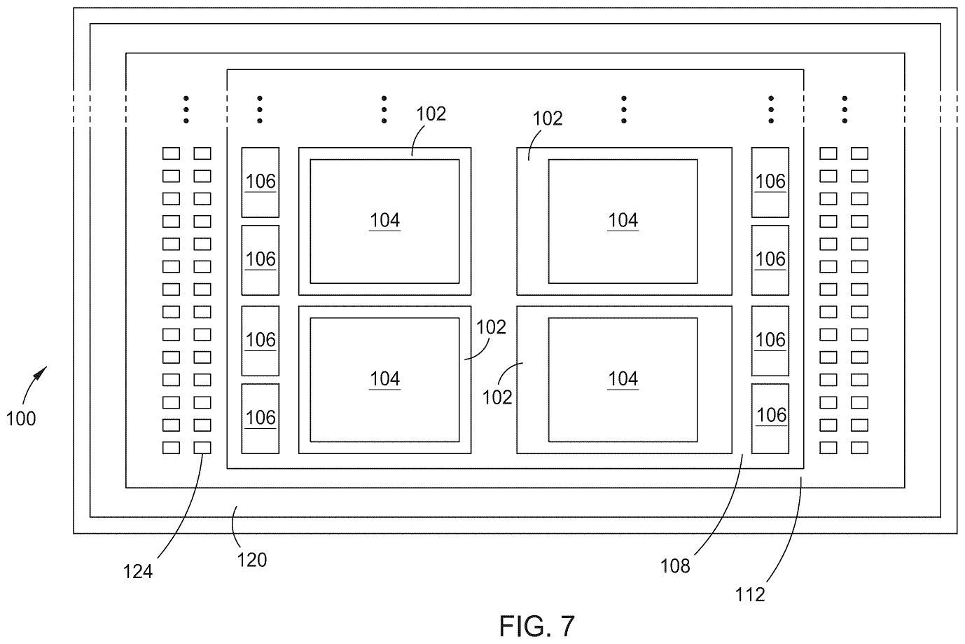

FIG. 7 is a schematic plan view of a portion of the chip package 100 illustrating relative exemplary positions of memory stacks 106, compute die stacks 104 and integrated circuit (IC) interposer dies 102, according to one example. In FIG. 7, the lid 122, TIM 130, mold compound 126 and metal layer 128 have been removed to allow the memory stacks 106, compute die stacks 104 and integrated circuit (IC) interposer dies 102 to be viewed more clearly.

As discussed above, the chip package 100 may be configured with as little as one memory stack 106, one compute die stack 104 and one integrated circuit (IC) interposer die 102. The chip package 100 may be alternatively be configured with one or more memory stacks 106, one or more compute die stacks 104 and one or more IC interposer dies 102. The one or more memory stacks 106, one or more compute die stacks 104 and one or more IC interposer dies 102 may be arranged symmetrically or asymmetrically. For example, the IC interposer dies 102 may be arranged in linearly or in a grid of rows and columns. In some examples, the IC interposer dies 102 may be arranged symmetrically about a bifurcating centerline of the interposer 108 in a 2×2, 3×3, 4×4 or other grid pattern. In other examples, an odd number of IC interposer dies 102 may be arranged in a grid pattern, with one location (i.e., node) of the grid either being free of an interposer die, and optionally having a dummy silicon structure in the node of the grid at which the interposer die has been omitted.

The compute die stacks 104 may be located between the interposer dies 102 and the nearest edge of the interposer 108. The compute die stacks 104 may be arranged in one or more columns (for example, 2 or 3 columns) between the interposer dies 102 and the nearest edge of the interposer 108. The compute die stacks 104 may be located on 2 sides of the interposer dies 102, such as along opposite edges of the interposer 108. One, two or more compute die stacks 104 may be overlapped with a single edge each interposer die 102.

In the exampled depicted in FIG. 7, the interposer dies 102 are arranged symmetrically about the bifurcating centerline of the interposer 108 in a 2×2 grid pattern. The interposer dies 102 may be evenly spaced. Two compute die stacks 104 are located between each interposer die 102 and the nearest edge of the interposer 108. The compute die stacks 104 are arranged in a single column on opposite sides of the interposer dies 102, adjacent the opposite edges of the interposer 108.

The chip package 100 depicted in FIG. 7 also include one or more columns of surface mounted components 124 mounted on the package substrate 112. The surface mounted components 124 are arranged on opposite sides of the interposer 108.

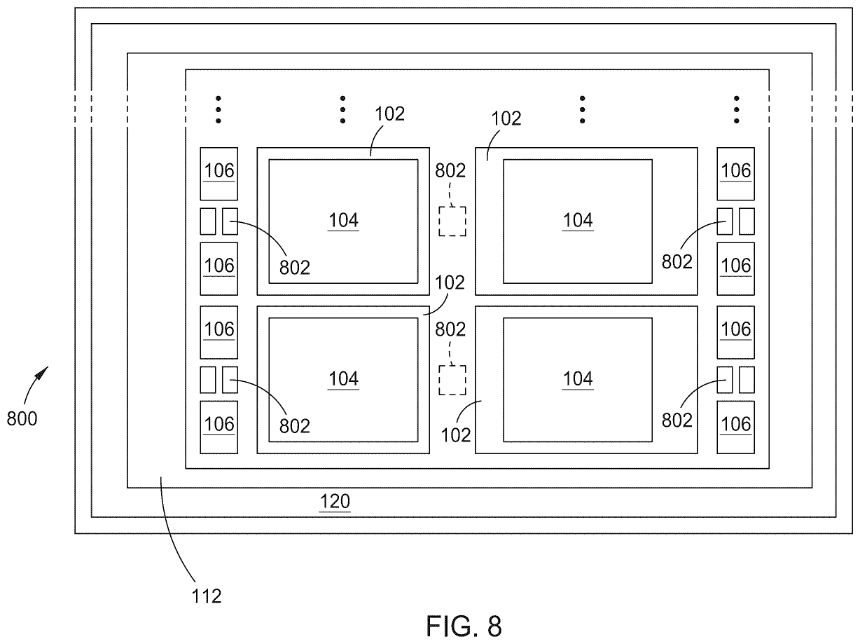

FIG. 8 is a schematic plan view of a portion of another chip package 800 illustrating relative exemplary positions of memory stacks 106, compute die stacks 104 and integrated circuit (IC) interposer dies 102, according to one example. In FIG. 8, the lid 122, TIM 130, mold compound 126 and metal layer 128 have been removed to allow the memory stacks 106, compute die stacks 104 and integrated circuit (IC) interposer dies 102 to be viewed more clearly The chip package 800 is may be configured similar to the chip packages 100, 200 discussed above, except in that the chip package 800 includes at least one integrated passive device (IPD) 802 coupled to or embedded with the interposer 108, rendering the surface mounted components 124 mounted on the package substrate 112 as optional.

In the example depicted in FIG. 8, one or more IPDs 802 may be mounted to or fabricated within the interposer 108 adjacent the memory stacks 106. In some examples, multiple IPDs 802 may be disposed within or on the interposer 108 between two adjacent memory stacks 106. Alternatively or in addition to mounting IPDs or forming the IPDs within the interposer 108 adjacent the memory stacks 106, one or more IPDs 802 may be disposed within or on the interposer 108 between two adjacent IC interposer dies 102. The IPDs 802 are electrically connected to the circuitry of the IC interposer die 102 through the routing 132 of the interposer 108. The IPD 802 may be a capacitor, an inductor, a resistor or other passive circuit element. In one example, the IPD 802 is a deep trench capacitor. The IPDs 802 may be formed as a solid state circuit as part of the fabrication of the interposer 108.

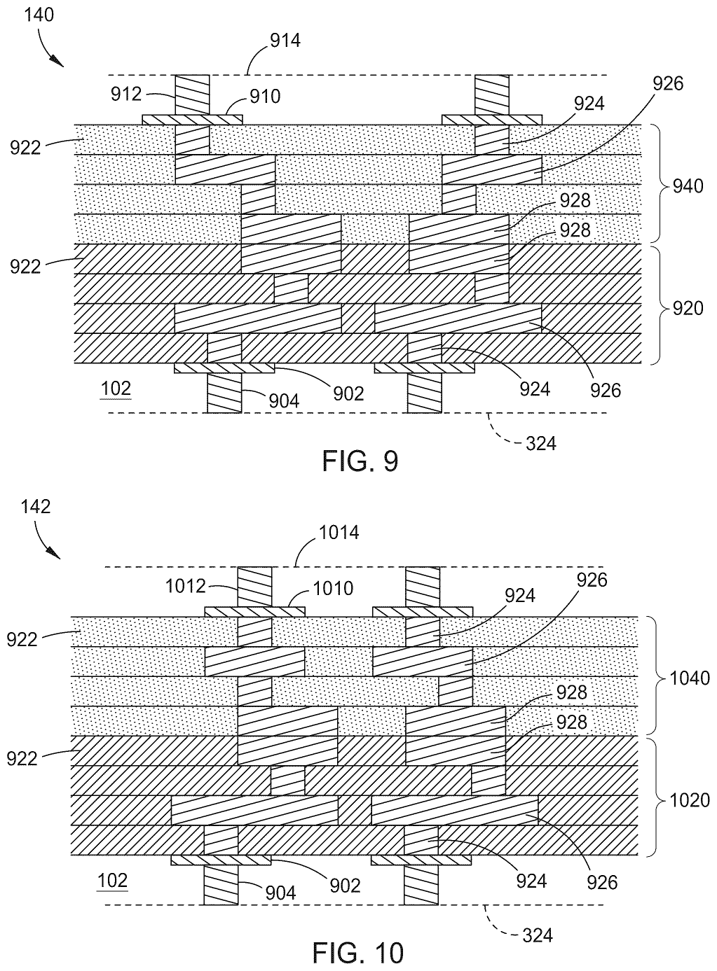

FIGS. 9 and 10 are partial sectional views of exemplary hybrid bonding interface between compute die 140/142 of compute die stacks 104 and an integrated circuit (IC) interposer die 102. The hybrid bonding interface is formed on the compute dies 140, 142 and the IC interposer die 102 after the dies 102, 140, 142 have been fabricated, thus enabling compute dies 140, 142 (or other dies) with different layouts of bond pads to be mounted to the same IC interposer die 102. This allows a singular IC interposer die design to be used with many different IC dies, thus increasing design flexibility, reducing costs, and reducing the time to market.

For example first referring to the partial sectional view of FIG. 9, a compute die 140 of a compute die stack 104 is illustrated as hybrid bonded to an IC interposer die 102. The compute die 140 includes exposed bond pads 910 having a first layout. The bond pads 910 are coupled by routing 912 to functional circuitry 914 within the compute die 140.

A hybrid bonding layer 940 is formed on the surface of the compute die 140 facing the IC interposer die 102. The hybrid bonding layer 940 includes a plurality of dielectric layers 922 separating conductive vias 924 and lines 926 that form routings through the hybrid bonding layer 940. Materials suitable for the dielectric layer 922 include oxides, thermal oxides, SiO₂, SiN, SiCN, polybenzoxazole (PBO), polyimide (PI), benzocyclobutene (BCB), among others. The vias 924 and lines 926 may be copper or other suitable electric conductor. At least one via 924 is coupled to a respective one of the exposed bond pads 910 formed on the bottom surface of compute die 140. The routing within the hybrid bonding layer 940 terminates at hybrid bonding pads 928.

Similarly, the IC interposer die 102 includes exposed bond pads 902 arranged in a pattern (e.g., layout). The bond pads 902 are coupled by routings 904 to the die to die PHY 324 of the functional circuitry disposed within the IC interposer die 102.

A hybrid bonding layer 920 is formed on the surface of the IC interposer die 102 facing the compute die 140. The hybrid bonding layer 920 includes a plurality of dielectric layers 922 separating conductive vias 924 and lines 926 that form routings through the hybrid bonding layer 940. At least one via 924 is coupled to a respective one of the exposed bond pads 910 formed on the bottom surface of the IC interposer die 102. The routing within the hybrid bonding layer 920 terminates at hybrid bonding pads 928.

Hybrid bonding the layers 920, 940 includes forming non-metal to non-metal bonds using fusion bonding, and forming metal-to-metal bonds across the adjacent IC dies 102, 140. The metal-to-metal bonds may be formed using pressure and heat to form eutectic metal bonds. In one example, a hybrid bond is formed by fusion bonding the dielectric materials of the layers 922 surrounding the hybrid bond pads 928 on each hybrid bonding layers 920, 940 to first secure the dies 102, 140 together, followed by an interfusion of the metal materials of the hybrid bond pads 928 of the facing hybrid bonding layers 920, 940 to create the electric interconnect between the functional circuitry 914 of the compute die 140 and the functional circuitry of the vertically adjacent IC interposer die 102.

The geometric layout of the routing made from the conductive vias 924 and lines 926 within the hybrid bonding layers 920, 940 may be fabricated as needed. The flexible configuration of the routing within the hybrid bonding layers 920, 940 allows multiple IC dies having different bond pad layouts to be mounted to the same IC interposer die 102 without need to fabricate a different IC interposer die having a different location of bond pads.

For example as shown in FIG. 10, the IC interposer die 102 has the identical layout of bond pads 902 as the IC interposer die 102 illustrated in FIG. 9. However, the layout of bond pads 1010 of the compute die 142 is different than the layer of bond pads 910 of the compute die 140. To accommodate the difference in bond pad layout between the compute dies 140, 142 while enabling the same IC interposer die 102 to be used, one or both of the hybrid bonding layers 1020, 1040 has a different configuration of vias 924 and lines 926 that enable the pads 928 of each layer 1020, 1040 to mate even though the locations of the pad 910, 1010 of the compute dies 140, 142 are physically different. This allows the functional circuitry 1014 coupled to the bond pad 1010 via routing 1012 of the compute die 142 to the die to die PHY 324 of the functional circuitry of the IC interposer die 102.

Also described herein is a method for fabricating a chip package, such as the chip package 100 or other similarly constructed chip package. The method begins by mounting a compute die stack 104 on an IC interposer die 102. The compute die stack 104 includes at least a first compute die 140 and a second compute die 142. The compute stack 104 may include additional compute dies, dummy dies, and the like as described above. The compute stack 104 may be mounted to the IC interposer die 102 via solder connections, hybrid bonding, or other suitable technique.

After the compute stack 104 has been mounted to the IC interposer die 102, the IC interposer die 102 is mounted to a substrate 112. The IC interposer die 102 may be mounted to the substrate 112 via solder connections, hybrid bonding, or other suitable technique.

Before, after, or simultaneously to the IC interposer die 102 being mounted to the substrate 112, a memory stack 106 is mounted to the substrate 112. The memory stack 106 may be mounted to the substrate 112 via solder connections, hybrid bonding, or other suitable technique.

Once the IC interposer die 102 and the memory stack 106 has been mounted to the substrate 112, the chip package 100 is formed. The chip package 100 may later be mounted to a printed circuit board (PCB) and be connected via PCB to other chip packages or memory within a local device, such as a server, or be coupled via a network to a remote electronic device, such as data center among others.

Thus, the chip packages disclosed above arrange memory stacks as a unified memory device efficiently available through a single IC interposer die. The single IC interposer die includes multiple compute dies that leverage hybrid bonding and high speed routing in an interposer to provide fast, high bandwidth communication with multiple memory stacks. The modular arrangement of the IC interposer die, memory stacks and compute dies makes the chip package readily scalable and adapted to be configured for various compute applications without the need for new die or interposer designs. As a result, the chip package provides increased application flexibility at reduced manufacturing costs.

In addition to the examples described above, the disclosed technology may also be expressed in the following non-limiting examples.

Example 1. A chip package including: a substrate; an integrated circuit (IC) interposer die mounted on the substrate; a compute die stack mounted on the IC interposer die; and a memory stack mounted on the substrate and electrically coupled to the compute die stack through the IC interposer die.

Example 2. The chip package of example 1, wherein the compute die stack further includes: at least a first compute die and a second compute die.

Example 3. The chip package of example 2, wherein the first compute die and the second compute die includes central processing unit (CPU) cores.

Example 4. The chip package of example 2, wherein the first compute die includes accelerated compute cores and the second compute die includes central processing unit (CPU) cores.

Example 5. The chip package of example 2, wherein the first compute die and the second compute die includes accelerated compute cores.

Example 6. The chip package of example 1, wherein the compute die stack further includes: a carrier die disposed over one or more compute dies.

Example 7. The chip package of example 6, wherein the carrier die is circuit free.

Example 8. The chip package of example 7, wherein the carrier die is fusion bonded to one or more of the compute dies with an oxide layer.

Example 9. The chip package of example 8 further including: mold compound disposed between the memory stack and the carrier die.

Example 10. The chip package of example 9 further including: a metal layer formed in contact with a top surface of the mold compound, a top surface of the memory stack, and a top surface of the carrier die.

Example 11. The chip package of example 10 further including: a lid disposed over the memory stack and the carrier die; and thermal interface material disposed in contact with both the metal layer and the lid.

Example 12. The chip package of example 11, wherein the thermal interface material is a liquid metal or phase change material.

Example 13. The chip package of example 1, wherein: the substrate is an interposer; and the interposer is mounted on a package substrate.

Example 14. The chip package of example 13 further including: surface mounted components mounted to the package substrate and electrically connected to the IC interposer die through the package substrate and interposer.

Example 15. The chip package of example 1 further including: at least one integrated passive device (IPD) mounted to the substrate and electrically connected to the IC interposer die through the substrate.

Example 16. The chip package of example 15, wherein the IPD comprise a deep trench capacitor.

Example 17. The chip package of example 16 further including: a carrier die disposed over one or more compute dies; mold compound disposed between the memory stack, the IPD and the carrier die; a metal layer formed in contact with a top surface of the mold compound, a top surface of the memory stack, a top surface of the IPD, and a top surface of the carrier die; a lid disposed over the memory stack, the IPD, and the carrier die; and thermal interface material disposed in contact with both the metal layer and the lid.

Example 18. The chip package of example 1, wherein the compute die stack further includes: a first compute die; a second compute die; a carrier die disposed over first and second compute dies; and a dummy die disposed between the IC interposer die and the carrier die.

Example 19. The chip package of example 18, wherein the dummy die is circuit free.

Example 20. The chip package of example 18, wherein the dummy die is fusion bonded to at least two of the first compute die, the second compute die, the IC interposer die, and the carrier die.

Example 21. The chip package of example 18, wherein the dummy die is fusion bonded to the IC interposer die between the second compute die and a first edge of the IC interposer die, the first compute die disposed between the second compute die and a second edge of the IC interposer die, the first and second compute dies and the dummy die disposed between the first and second edges of the IC interposer die.

Example 22. The chip package of example 2, wherein the first compute die is hybrid bonded to one or both of the second compute die and the IC interposer die.

Example 23. The chip package of example 2, wherein the IC interposer die further includes: memory controller circuity coupled to both the first and second compute dies without routing signals through the package substrate; and cache memory circuity coupled to both the first and second compute dies without routing signals through the package substrate.

Example 24. The chip package of example 2, wherein the IC interposer die further includes: a network on a chip (NOC) circuitry; peripheral component interconnect express (PCIe) circuity; memory physical layer (PHY) circuitry configured to communicate with the memory stack; die to die PHY configured to communicate with at least one of the first and second compute dies; and I/O PHY configured to communicate with a device remote from the chip package.

Example 25. The chip package of example 9, wherein a top surface of the mold compound, a top surface of the memory stack, and a top surface of the carrier die are coplanar.

Example 26. The chip package of example 13 further including: solder balls disposed on a bottom surface of the package substrate and electrically connected to the IC interposer die through routing formed through the package substrate and the interposer.

Example 27. The chip package of example 13 further including: contact pads exposed on a bottom surface of the package substrate and configured to interface with a socket.

Example 28. A chip package including: a substrate; a first integrated circuit (IC) interposer die mounted on the substrate, the first IC interposer die including memory controller circuity; a first compute die stack mounted on the first IC interposer die, the first compute die stack including at least a first compute die and a second compute die both communicatively coupled with the memory controller circuity; a first memory stack mounted on the substrate and electrically coupled to the memory controller circuity through the substrate; a lid disposed over the first memory stack and the first compute die stack; and thermal interface material disposed in contact with both the first compute die stack and the lid.

Example 29. The chip package of example 28 further including: a second compute die stack mounted on the first IC interposer die, the second compute die stack including a plurality of compute dies communicatively coupled with the memory controller circuity.

Example 30. The chip package of example 28 further including: a second memory stack mounted on the substrate and electrically coupled to the memory controller circuity through the substrate.

Example 31. The chip package of example 28 further including: a second IC interposer die mounted on the substrate, the second IC interposer die including memory controller circuity; a second compute die stack mounted on the second IC interposer die, the second compute die stack including a plurality of compute dies communicatively coupled with the memory controller circuity of the second IC interposer die; and a second memory stack mounted on the substrate and electrically coupled to the memory controller circuity of the second IC interposer die through the substrate.

Example 32. The chip package of example 28 further including: a metal layer formed in contact with a top surface of the first memory stack and a top surface of the first compute die stack.

Example 33. The chip package of example 32 further including: thermal interface material disposed in contact with both the metal layer and the lid.

Example 34. The chip package of example 33, wherein the thermal interface material is a liquid metal or phase change material.

Example 35. The chip package of example 32 further including: mold compound disposed between the first memory stack and the first compute die stack, wherein the metal layer is formed in contact with a top surface of the mold compound.

Example 36. The chip package of example 35, wherein the thermal interface material is a liquid metal or phase change material.

Example 37. The chip package of example 28, wherein the first compute die and the second compute die includes central processing unit (CPU) cores.

Example 38. The chip package of example 28, wherein the first compute die includes accelerated compute cores and the second compute die includes central processing unit (CPU) cores.

Example 39. The chip package of example 28, wherein the first compute die and the second compute die includes accelerated compute cores.

Example 40. The chip package of example 28, wherein the first compute die stack terminates at a carrier die, the carrier die disposed closer to the lid than the first IC interposer die.

Example 41. The chip package of example 40, wherein the carrier die is a circuit free block of silicon.

Example 42. The chip package of example 41, wherein the carrier die is fusion bonded to at least one of the first and second compute dies with an oxide layer.

Example 43. The chip package of example 28, wherein: the substrate is an interposer; and the interposer is mounted on a package substrate.

Example 44. The chip package of example 43 further including: at least one integrated passive device (IPD) mounted to the interposer and electrically connected to the first IC interposer die through the substrate.

Example 45. The chip package of example 44, wherein the IPD comprise a deep trench capacitor.

Example 46. The chip package of example 44 further including: mold compound disposed between the first memory stack, the IPD and the first die compute stack; a metal layer formed in contact with a top surface of the mold compound, a top surface of the first memory stack, a top surface of the IPD, and a top surface of the first die compute stack; and thermal interface material disposed in contact with both the metal layer and the lid.

Example 47. The chip package of example 28, wherein the first compute die stack further includes: a carrier die disposed over first and second compute dies; and a dummy die disposed between the first IC interposer die and the carrier die.

Example 48. The chip package of example 47, wherein the dummy die is circuit free.

Example 49. The chip package of example 48, wherein the dummy die is fusion bonded to at least two of the first compute die, the second compute die, the first IC interposer die, and the carrier die.

Example 50. The chip package of example 48, wherein the dummy die is fusion bonded to the first IC interposer die between the second compute die and a first edge of the first IC interposer die, the first compute die disposed between the second compute die and a second edge of the first IC interposer die, the first and second compute dies and the dummy die disposed between the first and second edges of the first IC interposer die.

Example 51. The chip package of example 28, wherein the first compute die is hybrid bonded to one or both of the second compute die and the first IC interposer die.

Example 52. The chip package of example 28, wherein the first IC interposer die further includes: cache memory circuity coupled to both the first and second compute dies without routing signals through the substrate.

Example 53. The chip package of example 52, wherein the IC interposer die further includes: a network on a chip (NOC) circuitry; peripheral component interconnect express (PCIe) circuity; memory physical layer (PHY) circuitry configured to communicate with the first memory stack; die to die PHY configured to communicate with at least one of the first and second compute dies; and I/O PHY configured to communicate with a device remote from the chip package.

Example 54. The chip package of example 28, wherein a top surface of the first memory stack and a top surface of the first compute die stack are exposed and coplanar.

Example 55. The chip package of example 43 further including: solder balls disposed on a bottom surface of the package substrate and electrically connected to the first IC interposer die through routing formed through the package substrate and the interposer.

Example 56. The chip package of example 43 further including: contact pads exposed on a bottom surface of the package substrate and configured to interface with a socket.

Example 57. A method for fabricating a chip package, the method including mounting a compute die stack on an integrated circuit (IC) interposer die, the compute die stack comprising at least two compute IC dies; mounting the IC interposer die on a substrate; and mounting a memory stack on the substrate, the memory stack electrically coupled to the compute die stack through the IC interposer die.

While the foregoing is directed to embodiments of the present invention, other and further embodiments of the invention may be devised without departing from the basic scope thereof, and the scope thereof is determined by the claims that follow.

What is claimed is:

1. A chip package comprising:
a substrate;
an integrated circuit (IC) interposer die mounted on the substrate;
a compute die stack mounted on the IC interposer die; and
a memory stack mounted on the substrate and electrically coupled to the compute die stack through the IC interposer die.

2. The chip package of claim 1, wherein the compute die stack further comprises:
at least a first compute die and a second compute die.

3. The chip package of claim 2, wherein the first compute die and the second compute die comprises central processing unit (CPU) cores.

4. The chip package of claim 2, wherein the first compute die comprises accelerated compute cores and the second compute die comprises central processing unit (CPU) cores.

5. The chip package of claim 2, wherein the first compute die and the second compute die comprises accelerated compute cores.

6. The chip package of claim 1, wherein the compute die stack further comprises:
mold compound disposed between the memory stack and the compute die stack; and
a metal layer formed in contact with a top surface of the mold compound, a top surface of the memory stack, and a top surface of the compute die stack.

7. The chip package of claim 6 further comprising:
a lid disposed over the memory stack and the compute die stack; and
thermal interface material disposed in contact with both the metal layer and the lid

8. The chip package of claim 1, wherein:
the substrate is an interposer; and
the interposer is mounted on a package substrate.

9. The chip package of claim 2, wherein the first compute die is hybrid bonded to one or both of the second compute die and the IC interposer die.

10. The chip package of claim 2, wherein the IC interposer die further comprises:
memory controller circuity coupled to both the first and second compute dies without routing signals through the package substrate; and
cache memory circuity coupled to both the first and second compute dies without routing signals through the substrate.

11. The chip package of claim 2, wherein the IC interposer die further comprises:
a network on a chip (NOC) circuitry;
peripheral component interconnect express (PCIe) circuity;
memory physical layer (PHY) circuitry configured to communicate with the memory stack;
die to die PHY configured to communicate with at least one of the first and second compute dies; and
I/O PHY configured to communicate with a device remote from the chip package.

12. A chip package comprising:
a substrate;
a first integrated circuit (IC) interposer die mounted on the substrate, the first IC interposer die comprising memory controller circuity;
a first compute die stack mounted on the first IC interposer die, the first compute die stack comprising at least a first compute die and a second compute die both communicatively coupled with the memory controller circuity;
a first memory stack mounted on the substrate and electrically coupled to the memory controller circuity through the substrate;
a lid disposed over the first memory stack and the first compute die stack; and
thermal interface material disposed in contact with both the first compute die stack and the lid.

13. The chip package of claim 12 further comprising:
a second compute die stack mounted on the first IC interposer die, the second compute die stack comprising a plurality of compute dies communicatively coupled with the memory controller circuity.

14. The chip package of claim 12 further comprising:
a second memory stack mounted on the substrate and electrically coupled to the memory controller circuity through the substrate.

15. The chip package of claim 12 further comprising:
a second IC interposer die mounted on the substrate, the second IC interposer die comprising memory controller circuity;
a second compute die stack mounted on the second IC interposer die, the second compute die stack comprising a plurality of compute dies communicatively coupled with the memory controller circuity of the second IC interposer die; and
a second memory stack mounted on the substrate and electrically coupled to the memory controller circuity of the second IC interposer die through the substrate.

16. The chip package of claim 12, wherein at least one or both of the first compute die and the second compute die comprises central processing unit (CPU) cores.

17. The chip package of claim 12, wherein at least one or both of the first compute die and the second compute die comprises accelerated compute cores.

18. The chip package of claim 12, wherein the first compute die stack further comprises:
a carrier die disposed over first and second compute dies; and
a circuit free dummy die disposed between the first IC interposer die and the carrier die, wherein the dummy die is fusion bonded to at least two of the first compute die, the second compute die, the first IC interposer die, and the carrier die.

19. The chip package of claim 12, wherein the first IC interposer die further comprises:
cache memory circuity coupled to both the first and second compute dies without routing signals through the substrate,
a network on a chip (NOC) circuitry;
peripheral component interconnect express (PCIe) circuity;
memory physical layer (PHY) circuitry configured to communicate with the first memory stack;
die to die PHY configured to communicate with at least one of the first and second compute dies; and
I/O PHY configured to communicate with a device remote from the chip package.

20. A method for fabricating a chip package, the method comprising:
mounting a compute die stack on an integrated circuit (IC) interposer die, the compute die stack comprising at least two compute IC dies;
mounting the IC interposer die on a substrate; and
mounting a memory stack on the substrate, the memory stack electrically coupled to the compute die stack through the IC interposer die.
